(19) United States
(12) Patent Application Publication
(10) Pub. No.: US 2004/0140527 A1
(43) Pub. Date: Jul. 22, 2004

(54) Semiconductor device having poly-poly capacitor

(75) Inventors: Keiichi Furuya, Hyogo (JP); Fumitoshi Yamamoto, Tokyo (JP); Yasuki Yoshihisa, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/618,695

(22) Filed: Jul. 15, 2003

(30) Foreign Application Priority Data
Jan. 21, 2003 (JP) 2003-11948

(51) Int. Cl. H01L 29/00

(52) U.S. Cl. 257/532

(57) ABSTRACT

Concerning a semiconductor device having a stacked capacitor including MOS and Poly-Poly capacitors, a semiconductor device structured without a need for excessive fine processing is provided. Also, a semiconductor device is provided which offers an increased capacitance density, while suppressing increases in manufacturing process and manufacturing cost. A highly-conductive diffusion layer doped with an N-type or P-type dopant is formed on a semiconductor substrate. A gate oxide film is formed in the surface of the highly-conductive diffusion layer by oxidizing the highly-conductive diffusion layer. A first polysilicon layer doped with an N-type or P-type dopant is formed on the gate oxide film. A dielectric layer is formed on the first polysilicon layer. A second polysilicon layer doped with an N-type or P-type dopant is formed on the dielectric layer. A first aluminum interconnection provided on an insulating layer is electrically connected to the highly-conductive diffusion layer and the second polysilicon layer through a contact hole.

### BACKGROUND OF THE INVENTION

1. Field of the Invention

The present invention relates to semiconductor devices, and particularly to a semiconductor device having a large-capacitance capacitor and eliminating the need for excessive fine processing.

2. Description of the Background Art

Capacitor components provided in conventional semiconductor devices include MOS capacitors and capacitors structured between polysilicon electrodes (hereinafter referred to as Poly-Poly capacitors), for example. Poly-Poly capacitors provide better linearity in V-C characteristic than MOS capacitors. Therefore Poly-Poly capacitors are higher-precision capacitor components than MOS capacitors. However, since the Poly-Poly capacitor structure is composed of a lower-electrode polysilicon layer and an upper-electrode polysilicon layer with a dielectric layer interposed between them, the need for formation of two polysilicon layers increases the manufacturing process steps.

Because of the recent miniaturization of various appliances and devices, the trend of semiconductor devices used therein is toward reduced chip area. The trend is toward chip area reduction also for the purpose of reducing cost. Reducing the chip area reduces the area for formation of capacitor components. Thus, keeping conventional capacitance in reduced area requires increasing the capacitance density of capacitor components. One solution to this problem is stacked capacitors with MOS and Poly-Poly capacitors. In a stacked MOS/Poly-Poly capacitor, a gate oxide film and a first polysilicon layer are stacked on a highly-conductive diffusion layer in a semiconductor substrate to form an MOS capacitor, and a dielectric layer and a second polysilicon layer are stacked on the first polysilicon layer to form a Poly-Poly capacitor.

In the stacked MOS/Poly-Poly capacitor, the MOS capacitor and the Poly-Poly capacitor thus share the first polysilicon layer, resulting in reduced manufacturing process steps and increased capacitance density. A detailed structure and manufacturing method of such a stacked MOS/Poly-Poly capacitor are described in Japanese Patent Application Laid-Open No. 2002-9163 (pp. 4-6, FIGS. 1-4).

The stacked MOS/Poly-Poly capacitor as shown above provides reduced manufacturing process steps and an increased capacitance density. However, since the stacked MOS/Poly-Poly capacitor has three electrodes, i.e. the highly-conductive diffusion layer, first polysilicon layer, and second polysilicon layer, it is necessary to form interconnections to the individual electrodes. Such interconnections are routed in a small area, with reduced interconnect widths and narrow interconnect pitch. Accordingly, the formation of interconnects requires excessive fine processing, which raises problems like difficult manufacture and increased cost.

Possible approaches for further increasing the capacitance density of stacked MOS/Poly-Poly capacitors include forming the dielectric layer with material having a higher dielectric constant and stacking additional Poly-Poly capacitors. However, such methods have problems like increased manufacturing process steps and increased manufacturing cost.

### SUMMARY OF THE INVENTION

Concerning a semiconductor device having a stacked capacitor of MOS and Poly-Poly capacitors, an object of the present invention is to provide a semiconductor device structured without a need for excessive fine processing. Another object is to provide a semiconductor device that offers an increased capacitance density while suppressing increases in manufacturing process and manufacturing cost.

According to a first aspect of the present invention, a semiconductor device includes an MOS capacitor and a Poly-Poly capacitor. The MOS capacitor includes a first-conductivity-type diffusion layer formed in a surface of a substrate, a gate oxide film formed on the first-conductivity-type diffusion layer, and a first polysilicon layer formed on the gate oxide film and doped with a dopant of the first conductivity type or a second conductivity type. The Poly-Poly capacitor is stacked on the MOS capacitor and includes the first polysilicon layer, a first dielectric layer formed on the first polysilicon layer, and a second polysilicon layer formed on the first dielectric layer and doped with a dopant of the first conductivity type or the second conductivity type. The first-conductivity-type diffusion layer and the second polysilicon layer are electrically connected to a same first metal interconnection.

In a semiconductor device having a stacked capacitor of MOS and Poly-Poly capacitors, the present invention provides a semiconductor device constructed without a need for excessive fine processing.

According to a second aspect of the invention, a semiconductor device includes a first Poly-Poly capacitor. The first Poly-Poly capacitor includes a spiral-shaped first polysilicon electrode, a spiral-shaped second polysilicon electrode formed parallel to the shape of the first polysilicon electrode, and a third dielectric layer interposed between the first polysilicon electrode and the second polysilicon electrode.

The semiconductor device of the invention provides a large-capacitance capacitor that utilizes the inter-line capacitance between the first polysilicon electrode and the second polysilicon electrode.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a semiconductor device according to a first preferred embodiment of the present invention;

FIG. 2 is a cross-sectional view of a semiconductor device according to a second preferred embodiment of the present invention;

FIG. 3 is a cross-sectional view of a semiconductor device according to a third preferred embodiment of the present invention;

FIG. 4 is a cross-sectional view of a semiconductor device according to a fourth preferred embodiment of the present invention;

FIG. 5 is a plan view of a Poly-Poly capacitor according to a fifth preferred embodiment of the present invention;

FIG. 6 is a cross-sectional view of the Poly-Poly capacitor of the fifth preferred embodiment of the present invention;

FIG. 7 is a cross-sectional view of a Poly-Poly capacitor according to a sixth preferred embodiment of the present invention;

FIGS. 8 and 9 are plan views of the Poly-Poly capacitor of the sixth preferred embodiment of the present invention; and

FIG. 10 is a cross-sectional view of a semiconductor device according to a seventh preferred embodiment of the present invention.

### DESCRIPTION OF THE PREFERRED EMBODIMENTS

The present invention is now specifically described referring to the drawings showing the preferred embodiments.

(First Preferred Embodiment)

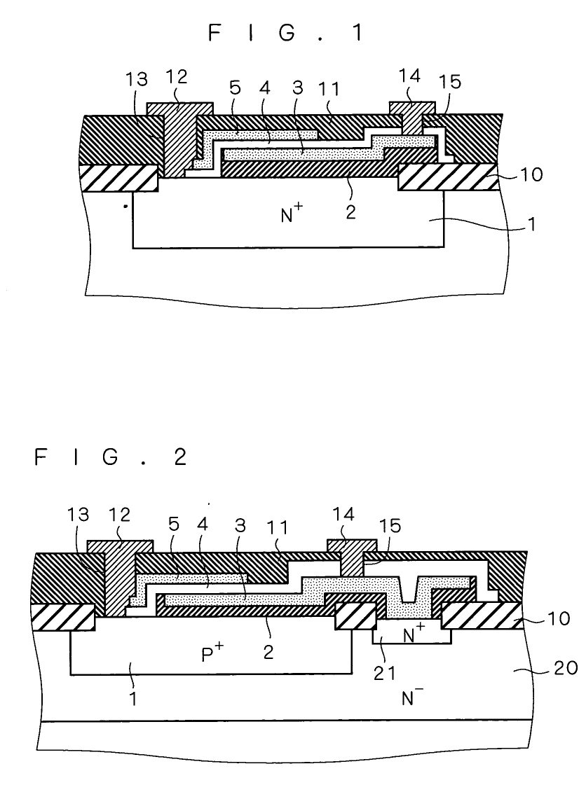

FIG. 1 is a cross-sectional view of a semiconductor device of a first preferred embodiment. A highly-conductive diffusion layer 1 doped with an N-type or P-type dopant is formed on a semiconductor substrate (the highly-conductive diffusion layer 1 of FIG. 1 is doped with an N-type dopant). Then the highly-conductive diffusion layer 1 is oxidized to form a gate oxide film 2 in the surface of the highly-conductive diffusion layer 1. Next, a first polysilicon layer 3 doped with an N-type or P-type dopant is formed on the gate oxide film 2. The highly-conductive diffusion layer 1 on the semiconductor substrate, the gate oxide film 2, and the first polysilicon layer 3 form an MOS capacitor.

Next, a dielectric layer 4 is formed on the first polysilicon layer 3. A second polysilicon layer 5 doped with an N-type or P-type dopant is formed on the dielectric layer 4. The first polysilicon layer 3, the dielectric layer 4, and the second polysilicon layer 5 form a Poly-Poly capacitor. In this preferred embodiment, the Poly-Poly capacitor is thus stacked on the MOS capacitor with the first polysilicon layer 3 shared as a common electrode. In FIG. 1, LOCOS (Local Oxidation of Silicon) 10 for element isolation is formed on the semiconductor substrate .

Next, an insulating layer 11 is formed over the dielectric layer 4 and the second polysilicon layer 5. Then a first aluminum interconnection 12 is formed on the insulating layer 11 and electrically connected to the highly-conductive diffusion layer 1 and the second polysilicon layer 5 trough a contact hole 13. That is to say, the highly-conductive diffusion layer 1 and the second polysilicon layer 5 are electrically connected by the same contact hole 13. A second aluminum interconnection 14 is formed on the insulating layer 11 and electrically connected to the first polysilicon layer 3 through a contact hole 15.

In this preferred embodiment, the first aluminum interconnection 12 is electrically connected to the highly-conductive diffusion layer 1 and the second polysilicon layer 5 through the contact hole 13. Accordingly, as compared with a conventional structure in which electric connections to the highly-conductive diffusion layer 1 and the second polysilicon layer 5 are made by separate aluminum interconnections, the first aluminum interconnection 12 can be disposed in a larger area. This allows a thicker width of the first aluminum interconnection 12 and wider interconnection intervals. Thus, in a semiconductor device having a stacked MOS/Poly-Poly capacitor, this preferred embodiment provides a semiconductor device that does not require excessive fine processing.

(Second Preferred Embodiment)

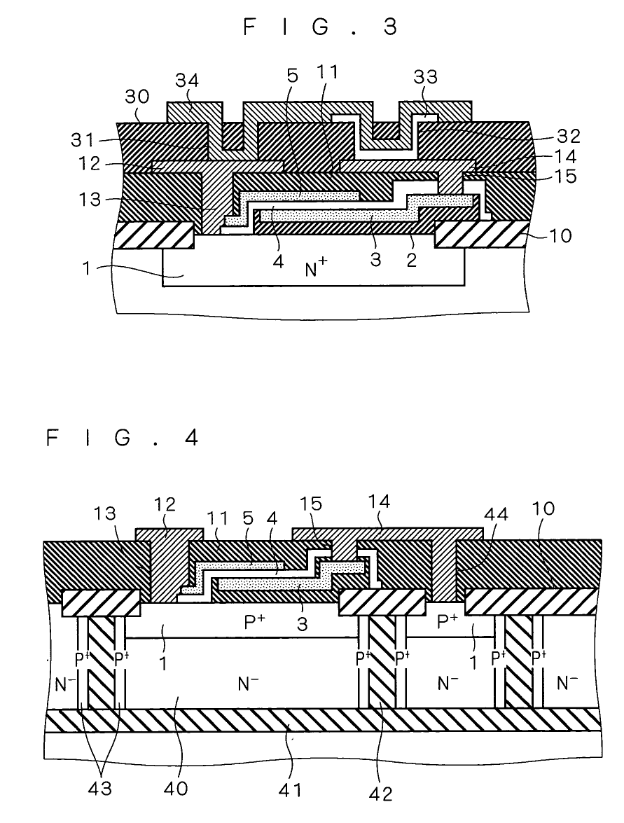

FIG. 2 is a cross-sectional view of a semiconductor device according to a second preferred embodiment. A diffusion layer 20 doped with an N-type or P-type dopant is formed on a semiconductor substrate. A highly-conductive diffusion layer 1, which is doped with a dopant of a different conductivity type from that of the diffusion layer 20, is formed on the diffusion layer 20 (in FIG. 2, the diffusion layer 20 is doped with an N-type dopant and the highly-conductive diffusion layer 1 is doped with a P-type dopant). The diffusion layer 20 and the highly-conductive diffusion layer 1 form a PN-junction capacitor.

Next, the highly-conductive diffusion layer 1 is oxidized to form gate oxide film 2 in the surface of the highly-conductive diffusion layer 1. First polysilicon layer 3 doped with a dopant of the same conductivity type as the diffusion layer 20 is formed on the gate oxide film 2. The highly-conductive diffusion layer 1 on the semiconductor substrate, the gate oxide film 2, and the first polysilicon layer 3 form an MOS capacitor.

Next, dielectric layer 4 is formed on the first polysilicon layer 3. Then second polysilicon layer 5 doped with an N-type or P-type dopant is formed on the dielectric layer 4. The first polysilicon layer 3, the dielectric layer 4, and the second polysilicon layer 5 form a Poly-Poly capacitor. This preferred embodiment thus provides a structure in which the MOS capacitor is stacked on the PN-junction capacitor with the highly-conductive diffusion layer 1 sheared as a common electrode and the Poly-Poly capacitor is stacked on the MOS capacitor with the first polysilicon layer 3 shared as a common electrode.

Next, insulating layer 11 is formed over the dielectric layer 4 and the second polysilicon layer 5. Then first aluminum interconnection 12 is formed on the insulating layer 11 and electrically connected to the highly-conductive diffusion layer 1 and the second polysilicon layer 5 through contact hole 13. That is to say, the highly-conductive diffusion layer 1 and the second polysilicon layer 5 are electrically connected by the same contact hole 13. Also, second aluminum interconnection 14 is formed on the insulating layer 11 and electrically connected to the first polysilicon layer 3 through contact hole 15. Furthermore, with the semiconductor substrate surface divided by LOCOS 10 into individual element regions, a highly-conductive diffusion layer 21 doped with a dopant of the same conductivity type as the diffusion layer 20 is formed in the portion of the diffusion layer 20 that is isolated by the LOCOS 10 from the adjacent element region in which the highly-conductive diffusion layer 1 resides (in FIG. 2, the highly-conductive diffusion layer 21 is doped with an N-type dopant). This highly-conductive diffusion layer 21 is electrically connected with the first polysilicon layer 3. The MOS capacitor, Poly-Poly capacitor, and PN-junction capacitor are thus connected in parallel.

In this preferred embodiment, the diffusion layer 20 doped with a dopant of a different conductivity type from the highly-conductive diffusion layer 1 is provided under the highly-conductive diffusion layer 1 of the MOS capacitor of the first preferred embodiment, where the junction surface between the highly-conductive diffusion layer 1 and the diffusion layer 20 forms a PN-junction capacitor. Thus, as in the first preferred embodiment, the interconnect width of the first aluminum interconnection 12 can be larger and interconnect intervals can be wider, and a semiconductor device not requiring excessive fine processing is thus provided. Moreover, in this preferred embodiment, a PN-junction capacitor can be formed just by adding simple manufacturing process while utilizing the structure of the first preferred embodiment; a semiconductor device with a higher capacitance density is thus provided.

(Third Preferred Embodiment)

FIG. 3 is a cross-sectional view of a semiconductor device according to a third preferred embodiment. This preferred embodiment provides a structure in which an MIM (Metal-Insulator-Metal) capacitor is stacked on the stacked MOS/Poly-Poly capacitor. Therefore, the same parts as those of FIG. 1 of the first preferred embodiments are shown by the same reference numerals in FIG. 3.

In FIG. 3, the highly-conductive diffusion layer 1 on the semiconductor substrate, gate oxide film 2, and first polysilicon layer 3 form an MOS capacitor, and the first polysilicon layer 3, dielectric layer 4, and second polysilicon layer 5 form a Poly-Poly capacitor. The first aluminum interconnection 12 is formed on the insulating layer 11 and electrically connected to the highly-conductive diffusion layer 1 and the second polysilicon layer 5 through the contact hole 13. The second aluminum interconnection 14 is formed on the insulating layer 11 and electrically connected to the first polysilicon layer 3 through the contact hole 15.

An insulating layer 30 is formed over the first aluminum interconnection 12 and the second aluminum interconnection 14. The insulating layer 30 has a contact hole 31 for connection to the first aluminum interconnection 12 and a contact hole 32 for connection to the second aluminum interconnection 14. A dielectric layer 33 is provided in the contact hole 32. Then a third aluminum interconnection 34 is provided in the contact hole 31 and the contact hole 32. In the contact hole 32, an MIM capacitor is formed in which the dielectric layer 33 and the third aluminum interconnection 34 are stacked on the second aluminum interconnection 14. Thus, the MOS capacitor, Poly-Poly capacitor, and MIM capacitor are connected in parallel.

In this preferred embodiment, while utilizing the second aluminum interconnection 14 connected to the first polysilicon layer 3 of the Poly-Poly capacitor of the first preferred embodiment, an MIM capacitor is constructed by stacking the dielectric layer 33 and the third aluminum interconnection 34 thereon. Thus, as in the first preferred embodiment, the interconnection width of the first aluminum interconnection 12 can be thicker and the interconnection intervals can be larger; a semiconductor device not requiring excessive fine processing is thus provided. Furthermore, according to this preferred embodiment, an MIM capacitor can be added just by adding simple manufacturing process, while utilizing the structure of the first preferred embodiment; a semiconductor device with a high capacitance density is thus provided.

(Fourth Preferred Embodiment)

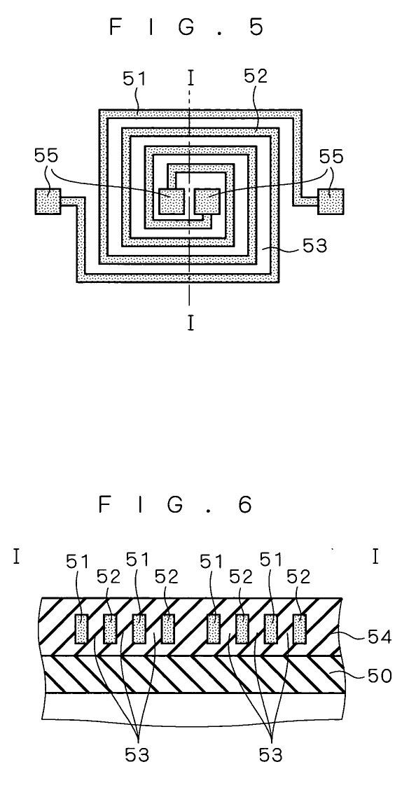

FIG. 4 is a cross-sectional view of a semiconductor device of a fourth preferred embodiment. This preferred embodiment provides a structure in which trench oxide film capacitors are added to the stacked capacitor having MOS and Poly-Poly capacitors. Therefore the same parts as those of FIG. 1 of the first preferred embodiment are shown by the same reference numerals in FIG. 4.

In FIG. 4, the highly-conductive diffusion layer 1 on the semiconductor substrate, gate oxide film 2, and first polysilicon layer 3 form an MOS capacitor, and the first polysilicon layer 3, dielectric layer 4, and second polysilicon layer 5 form a Poly-Poly capacitor. The first aluminum interconnection 12 is formed on the insulating layer 11 and electrically connected with the highly-conductive diffusion layer 1 and second polysilicon layer 5 through the contact hole 13.

Furthermore, a diffusion layer 40 is formed under the highly-conductive diffusion layer 1; the diffusion layer 40 is doped with a dopant of a conductivity type different from that of the highly-conductive diffusion layer 1. A buried oxide film 41 is formed under the diffusion layer 40. The highly-conductive diffusion layer 1 and the diffusion layer 40 are divided into individual element regions by trench oxide film layers 42. Side-wall diffusion layers 43 are formed on both side walls of the trench oxide film layers 42; the side-wall diffusion layers 43 are doped with a dopant of the same conductivity type as the highly-conductive diffusion layer 1. Thus, the trench oxide film layers 42 and the side-wall diffusion layers 43 form trench oxide film capacitors, where the trench oxide film layer 42 serves as the dielectric layer and the side-wall diffusion layers 43 serve as two electrodes. Now, in devices to which high voltage is applied, the side-wall diffusion layers 43 are used also to suppress depletion occurring from the buried oxide film 41 and to suppress voltage applied to the trench isolation oxide film layers 42.

Second aluminum interconnection 14 is formed on the insulating layer 11. The second aluminum interconnection 14 is electrically connected to the first polysilicon layer 3 through the contact hole 15. The second aluminum interconnection 14 is electrically connected also to the highly-conductive diffusion layer 1 through a contact hole 44. The portion of the highly-conductive diffusion layer 1 that is connected with the second aluminum interconnection 14 resides in the element region that is adjacent to the element region where the Poly-Poly capacitor is formed, with the trench oxide film layer 42 interposed between them. Thus the MOS capacitor, Poly-Poly capacitor, and trench oxide film capacitors are connected in parallel.

This preferred embodiment utilizes the stacked MOS/Poly-Poly capacitor of the first preferred embodiment and separately provides the trench oxide film layers 42 and side-wall diffusion layers 43 to form trench oxide film capacitors. Thus, as in the first preferred embodiment, the interconnection width of the first aluminum interconnection 12 can be larger and the interconnection intervals can be wider; a semiconductor device not requiring excessive fine processing is thus provided. In a semiconductor device using SOI, the trench oxide film layers 42 can be formed during the manufacturing process for isolating element formation regions, so that no additional process is needed. Also, in a semiconductor device with SOI, the trench oxide film layers 42 have high voltage resistance, and a semiconductor device having a high-voltage capacitor with a high capacitance density is thus provided.

(Fifth Preferred Embodiment)

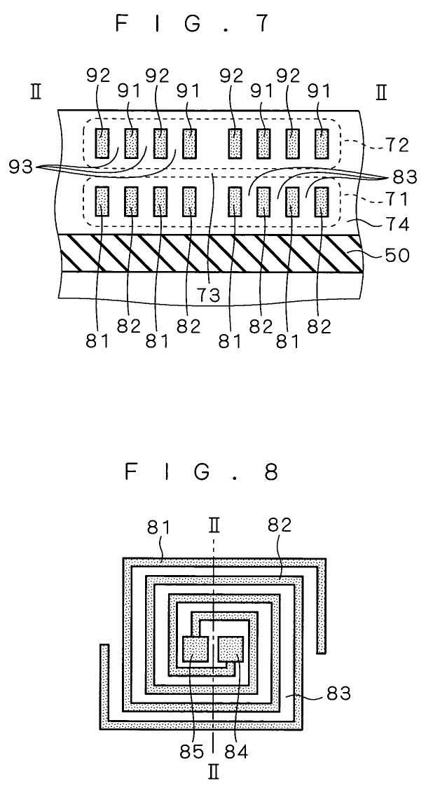

FIG. 5 is a plan view of a Poly-Poly capacitor according to a fifth preferred embodiment. FIG. 6 is a cross-sectional view of the Poly-Poly capacitor of this preferred embodiment. FIG. 6 shows the section taken along line I-I of FIG. 5. The Poly-Poly capacitor of this preferred embodiment is formed on LOCOS 50 formed by oxidizing the semiconductor substrate. This Poly-Poly capacitor is formed of a first polysilicon electrode 51 that is shaped in a spiral, a second polysilicon electrode 52 that extends in a spiral parallel along the shape of the first polysilicon electrode 51, and a first dielectric layer 53 interposed between them.

As shown in FIG. 6, the first polysilicon electrode 51 and the second polysilicon electrode 52 are formed in an interlayer insulating layer 54, where the interlayer insulating layer 54 serves as the first dielectric layer 53. Contact holes 55 for connection with other interconnections are formed at both ends of the first polysilicon electrode 51 and the second polysilicon electrode 52. The first polysilicon electrode 51 and the second polysilicon electrode 52 are doped with an N-type or P-type dopant.

The spiral-shaped Poly-Poly capacitor of this preferred embodiment provides a large-capacitance capacitor utilizing the inter-line capacitance between the first polysilicon electrode 51 and the second polysilicon electrode 52. Further, the first polysilicon electrode 51 and the second polysilicon electrode 52 can be formed during the formation of the gates of MOS transistors. Thus the spiral-shaped Poly-Poly capacitor of this preferred embodiment can be formed without a need for additional manufacturing process. This preferred embodiment thus provides a semiconductor device with a high capacitance density without a need for extra manufacturing process.

As for a modification of the Poly-Poly capacitor of this preferred embodiment, a large-capacitance capacitor with a still higher capacitance density can be obtained by replacing the first dielectric layer 53 between the first polysilicon electrode 51 and second polysilicon electrode 52 with a material having a higher dielectric constant than the interlayer insulating layer 54. Since this just involves replacing the interlayer insulating layer 54 with another material having a higher dielectric constant only between the first polysilicon electrode 51 and the second polysilicon electrode 52, the capacitance density of the Poly-Poly capacitor of this preferred embodiment can be enhanced without adversely affecting performance of other elements of the semiconductor device.

(Sixth Preferred Embodiment)

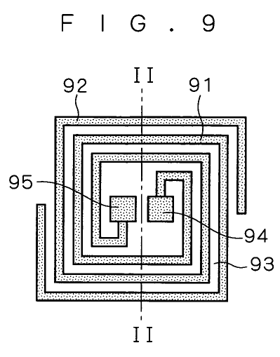

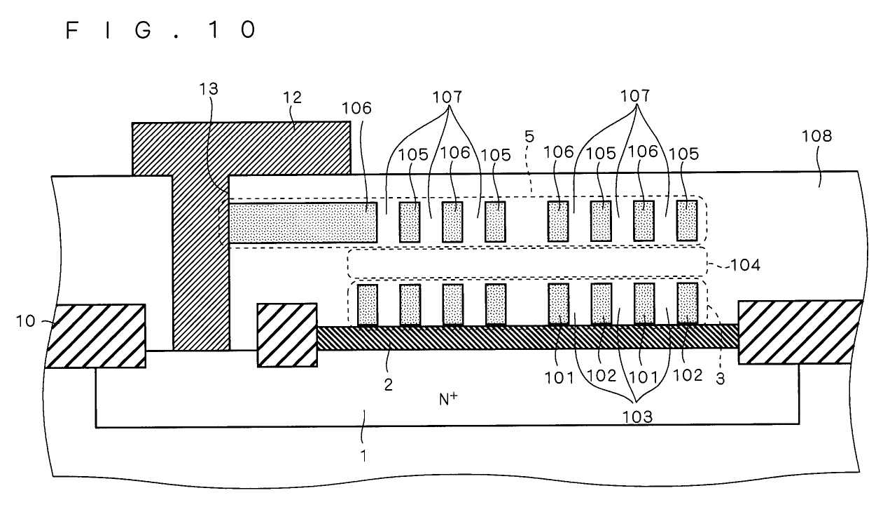

FIG. 7 is a cross-sectional view of a Poly-Poly capacitor of a sixth preferred embodiment. FIGS. 8 and 9 are plan views of the Poly-Poly capacitor of this preferred embodiment. FIG. 7 shows the section taken along line II-II of FIGS. 8 and 9. The Poly-Poly capacitor of this preferred embodiment, too, is formed on LOCOS 50 formed by oxidizing the semiconductor substrate. First, the spiral-shaped Poly-Poly capacitor 71 shown in FIG. 8 (the lower one in FIG. 7) is formed of a spiral-shaped first polysilicon electrode 81, a second polysilicon electrode 82 shaped in a spiral extending parallel along the shape of the first polysilicon electrode 81, and a first dielectric layer 83 interposed between them.

Next, the spiral-shaped Poly-Poly capacitor 72 shown in FIG. 9 (the upper one in FIG. 7) is formed of a spiral-shaped third polysilicon electrode 91, a fourth polysilicon electrode 92 shaped in a spiral extending parallel to the shape of the third polysilicon electrode 91, and a second dielectric layer 93 interposed between them. In this preferred embodiment, in addition to stacking two layers of spiral-shaped Poly-Poly capacitors of the fifth preferred embodiment, a third dielectric layer 73 is interposed between the Poly-Poly capacitor 71 serving as the lower electrode and the Poly-Poly capacitor 72 serving as the upper electrode, so as to form a parallel-electrode Poly-Poly capacitor.

That is to say, as shown in FIG. 7, the fourth polysilicon electrode 92 is disposed right above the first polysilicon electrode 81 and the third polysilicon electrode 91 is disposed right above the second polysilicon electrode 82, with the third dielectric layer 73 interposed between them. The end 84 of the first polysilicon electrode 81 and the end 94 of the third polysilicon electrode 91, and the end 85 of the second polysilicon electrode 82 and the end 95 of the fourth polysilicon electrode 92, are electrically connected through respective contact holes (not shown). The contact holes are filled with metal interconnection, e.g. of aluminum. The first polysilicon electrode 81 and the second polysilicon electrode 82 are connected to different interconnections (not shown).

As shown in FIG. 7, the first polysilicon electrode 81, second polysilicon electrode 82, third polysilicon electrode 91, and fourth polysilicon electrode 92 are formed in the interlayer insulating layer 74, so that the interlayer insulating layer 74 serves as the first dielectric layer 83, second dielectric layer 93, and third dielectric layer 73. The first polysilicon electrode 81, second polysilicon electrode 82, third polysilicon electrode 91, and fourth polysilicon electrode 92 are doped with an N-type or P-type dopant.

The Poly-Poly capacitor of this preferred embodiment provides a large-capacitance capacitor formed of a combination of capacitors including: the spiral-shaped Poly-Poly capacitor 71 that utilizes the inter-line capacitance between the first polysilicon electrode 81 and the second polysilicon electrode 82; the spiral-shaped Poly-Poly capacitor 72 that utilizes the inter-line capacitance between the third polysilicon electrode 91 and fourth polysilicon electrode 92; and the parallel-electrode Poly-Poly capacitor using the Poly-Poly capacitor 71 as the lower electrode and the Poly-Poly capacitor 72 as the upper electrode. Thus the Poly-Poly capacitor of this preferred embodiment offers an enhanced capacitance density.

Furthermore, the first polysilicon electrode 81, second polysilicon electrode 82, third polysilicon electrode 91, and fourth polysilicon electrode 92 can be formed during the formation of the gates of MOS transistors. Therefore the Poly-Poly capacitor of this preferred embodiment can be manufactured without a need for additional manufacturing process. Thus this preferred embodiment provides a semiconductor device with a high capacitance density without additional manufacturing process.

As for a modification of the Poly-Poly capacitor of this preferred embodiment, a large-capacitance capacitor with a still higher capacitance density can be obtained by replacing the first dielectric layer 83, second dielectric layer 93, and third dielectric layer 73 with a material having a higher dielectric constant than the interlayer insulating layer 74. Since this just involves replacing the interlayer insulating layer 74 with another material having a higher dielectric constant only for the first dielectric layer 83, second dielectric layer 93, and third dielectric layer 73, the capacitance density of the Poly-Poly capacitor of this preferred embodiment can be enhanced without adversely affecting performance of other elements of the semiconductor device.

As for another modification of this preferred embodiment, instead of electrically connecting the end 84 and the end 94, and the end 85 and the end 95, respectively through metal interconnections of, e.g. aluminum, the polysilicon layer forming the first polysilicon electrode 81 may be directly connected to the third polysilicon electrode 91, and the polysilicon layer forming the second polysilicon electrode 82 may be directly connected to the fourth polysilicon electrode 92. This eliminates the need for formation of metal interconnections of aluminum or the like for connecting the individual polysilicon electrodes, thereby reducing the manufacturing process.

(Seventh Preferred Embodiment)

FIG. 10 is a cross-sectional view of a semiconductor device according to a seventh preferred embodiment. The semiconductor device of this preferred embodiment provides a structure in which, in the stacked MOS/Poly-Poly capacitor of the first preferred embodiment, the Poly-Poly capacitor portion is replaced by the Poly-Poly capacitor shown in the sixth preferred embodiment.

Highly-conductive diffusion layer 1 doped with an N-type or P-type dopant is formed on the semiconductor substrate (the highly-conductive diffusion layer 1 of FIG. 10 is doped with an N-type dopant). Gate oxide film 2 is formed in the surface of the highly-conductive diffusion layer 1 by oxidizing the highly-conductive diffusion layer 1. A first polysilicon layer 3 doped with an N-type or P-type dopant is formed on the gate oxide film 2. The first polysilicon layer 3 of this preferred embodiment is composed of a spiral-shaped first polysilicon electrode 101, a second polysilicon electrode 102 shaped in a spiral parallel to the shape of the first polysilicon electrode 101, and a first dielectric layer 103 interposed between them. Thus the highly-conductive diffusion layer 1 on the semiconductor substrate, the gate oxide film 2, and the first polysilicon layer 3 form an MOS capacitor.

Next, a dielectric layer 104 is formed on the first polysilicon layer 3. Further, a second polysilicon layer 5 doped with an N-type or P-type dopant is formed on the dielectric layer 104. The second polysilicon layer 5 of this preferred embodiment is composed of a spiral-shaped third polysilicon electrode 105, a fourth polysilicon electrode 106 shaped in a spiral parallel to the shape of the third polysilicon electrode 105, and a second dielectric layer 107 between them. Thus the first polysilicon layer 3, dielectric layer 104, and second polysilicon layer 5 form a Poly-Poly capacitor.

As shown in FIG. 10, the fourth polysilicon electrode 106 is provided right above the first polysilicon electrode 101, and the third polysilicon electrode 105 is provided right above the second polysilicon electrode 102, with the third dielectric layer 104 interposed between them. An end of the first polysilicon electrode 101 and an end of the third polysilicon electrode 105, and an end of the second polysilicon electrode 102 and an end of the fourth polysilicon electrode 106, are electrically connected through respective contact holes (not shown). These contact holes are filled with metal interconnections, e.g. of aluminum. This preferred embodiment provides a structure in which the Poly-Poly capacitor is stacked on the MOS capacitor with the first polysilicon layer 3 serving as a common electrode. As shown in FIG. 10, the first polysilicon electrode 101, second polysilicon electrode 102, third polysilicon electrode 105, and fourth polysilicon electrode 106 are formed in the interlayer insulating layer 108, so that the interlayer insulating layer 108 serves as the first dielectric layer 103, second dielectric layer 107, and dielectric layer 104.

Next, first aluminum interconnection 12 is formed on the interlayer insulating layer 108. The first aluminum interconnection 12 is electrically connected to the highly-conductive diffusion layer 1 and the second polysilicon layer 5 through the contact hole 13. That is to say, the highly-conductive diffusion layer 1 and the second polysilicon layer 5 are electrically connected by the same contact hole 13.

In this preferred embodiment, as in the first preferred embodiment, the first aluminum interconnection 12 is thus electrically connected to the highly-conductive diffusion layer 1 and the second polysilicon layer 5 through the contact hole 13. This allows an increased area for the first aluminum interconnection 12, as compared with a conventional structure in which the highly-conductive diffusion layer 1 and the second polysilicon layer 5 are separately electrically connected with aluminum interconnections. This allows a thicker interconnection width of the first aluminum interconnection 12 and wider interconnection intervals.

Moreover, in this preferred embodiment, in addition to the stacked MOS/Poly-Poly capacitor of the first preferred embodiment, spiral-shaped Poly-Poly capacitors as shown in FIG. 5 are provided in the first polysilicon layer 3 and the second polysilicon layer 5. Accordingly, the capacitance density can be increased as compared with that of the first preferred embodiment by the inter-line capacitance between the first polysilicon electrode 101 and second polysilicon electrode 102 and the inter-line capacitance between the third polysilicon electrode 105 and the fourth polysilicon electrode 106. This preferred embodiment thus provides a semiconductor device with a higher capacitor density just by processing existing polysilicon layers, without adding any extra capacitor.

As for a modification of the semiconductor device of this preferred embodiment, a large-capacitance capacitor with a still higher capacitance density can be obtained by replacing the first dielectric layer 103, second dielectric layer 107, and dielectric layer 104 with a material having a higher dielectric constant than the interlayer insulating layer 108. Since this just involves replacing the interlayer insulating layer 108 with another material having a higher dielectric constant only for the first dielectric layer 103, second dielectric layer 107 and dielectric layer 104, the capacitance density of the semiconductor device of this preferred embodiment can be enhanced without adversely affecting the performance of other elements of the semiconductor device.

As for another modification of this preferred embodiment, instead of electrically connecting an end of the first polysilicon electrode 101 and an end of the third polysilicon electrode 105, and an end of the second polysilicon electrode 102 and an end of the fourth polysilicon electrode 106 through respective contact holes, the first polysilicon electrode 101 may be connected directly to the third polysilicon electrode 105 and the second polysilicon electrode 102 may be connected directly to the fourth polysilicon electrode 106. This eliminates the need for formation of contact holes and metal interconnections for connecting individual electrodes, thereby reducing the manufacturing process.

While the invention has been described in detail, the foregoing description is in all aspects illustrative and not restrictive. It is understood that numerous other modifications and variations can be devised without departing from the scope of the invention.

What is claimed is:

1. A semiconductor device comprising:
an MOS capacitor that comprises,
a first-conductivity-type diffusion layer formed in a surface of a substrate,
a gate oxide film formed on said first-conductivity-type diffusion layer, and
a first polysilicon layer formed on said gate oxide film and doped with a dopant of the first conductivity type or a second conductivity type; and
a Poly-Poly capacitor that comprises,
said first polysilicon layer,
a first dielectric layer formed on said first polysilicon layer, and
a second polysilicon layer formed on said first dielectric layer and doped with a dopant of the first conductivity type or the second conductivity type,
said Poly-Poly capacitor being stacked on said MOS capacitor, and
said first-conductivity-type diffusion layer and said second polysilicon layer being electrically connected to a same first metal interconnection.

2. The semiconductor device according to claim 1, further comprising a PN-junction capacitor comprising said first-conductivity-type diffusion layer and a second-conductivity-type diffusion layer formed under said first-conductivity-type diffusion layer,
wherein said first polysilicon layer, doped with a dopant of the second conductivity type, is electrically connected to said second-conductivity-type diffusion layer.

3. The semiconductor device according to claim 1, further comprising an MIM capacitor comprising:
a second metal interconnection electrically connected to said first polysilicon layer;
a second dielectric layer formed on said second metal interconnection; and
a third metal interconnection formed on said second dielectric layer and electrically connected with said first metal interconnection.

4. The semiconductor device according to claim 1,
wherein a second-conductive-type diffusion layer is formed under said first-conductivity-type diffusion layer, and
said semiconductor device further comprises a trench isolation oxide film capacitor comprising:
a trench isolation oxide film isolating said first-conductivity-type diffusion layer and said second-conductivity-type diffusion layer into individual element regions; and
first-conductivity-type trench side-wall diffusion layers formed on both side walls of said trench isolation oxide film, a portion of said first-conductivity-type trench side-wall diffusion layers being connected with said first-conductivity-type diffusion layer,
and wherein second metal interconnection electrically connects said first polysilicon layer and a portion of said first-conductivity-type diffusion layer that is in an element region adjacent to the element region where said MOS capacitor resides, with said trench isolation oxide film interposed therebetween.

5. A semiconductor device comprising:
a first Poly-Poly capacitor that comprises,
a spiral-shaped first polysilicon electrode,
a spiral-shaped second polysilicon electrode formed parallel to the shape of said first polysilicon electrode, and
a third dielectric layer interposed between said first polysilicon electrode and said second polysilicon electrode.

6. The semiconductor device according to claim 5, wherein said third dielectric layer has a higher dielectric constant than an interlayer insulating film formed on the semiconductor substrate.

7. The semiconductor device according to claim 5, further comprising a second Poly-Poly capacitor that comprises:
a spiral-shaped third polysilicon electrode;
a spiral-shaped fourth polysilicon electrode formed parallel to the shape of said third polysilicon electrode; and
a fourth dielectric layer interposed between said third polysilicon electrode and said fourth polysilicon electrode,
wherein said second Poly-Poly capacitor is disposed over said first Poly-Poly capacitor with a fifth dielectric layer interposed therebetween, with said fourth polysilicon electrode located above said first polysilicon electrode and said third polysilicon electrode located above said second polysilicon electrode, and
said first polysilicon electrode and said third polysilicon electrode are electrically connected to each other, and said second polysilicon electrode and said fourth polysilicon electrode are electrically connected to each other.

8. The semiconductor device according to claim 7, wherein said first polysilicon electrode and said third polysilicon electrode are directly connected to each other, and said second polysilicon electrode and said fourth polysilicon electrode are directly connected to each other.

9. The semiconductor device according to claim 7, wherein said third dielectric layer, said fourth dielectric layer, and said fifth dielectric layer have a higher dielectric constant than an interlayer insulating layer formed on the semiconductor substrate.

10. The semiconductor device according to claim 7, further comprising an MOS capacitor that comprises:
said first polysilicon electrode and said second polysilicon electrode;
a gate oxide film formed under said first polysilicon electrode and said second polysilicon electrode; and
a diffusion layer formed under said gate oxide film and having a first conductivity type or a second conductivity type,
wherein said fourth polysilicon electrode and said diffusion layer are electrically connected to a same metal interconnection.
